(19) United States
(12) Patent Application Publication
(10) Pub. No.: US 2022/0357650 A1
(43) Pub. Date: Nov. 10, 2022

(54) METAL PLATING WITH LUBRICANT

(71) Applicant: ENTEGRIS, INC., Billerica, MA (US)

(72) Inventors: Huaping Wang, Eden Prairie, MN (US); Russ V. Raschke, Chanhassen, MN (US)

(21) Appl. No.: 17/738,304

(22) Filed: May 6, 2022

Related U.S. Application Data
(60) Provisional application No. 63/185,711, filed on May 7, 2021.

(51) Int. Cl. G03F 1/66; H01L 21/673; C23C 18/32

(52) U.S. Cl. CPC G03F 1/66; H01L 21/67359; H01L 21/67366; C23C 18/32

(57) ABSTRACT

This technical disclosure describes a device that includes a recital pod and the method of making and maintaining the pod. The device includes a pod that includes a cover including a cover body; a baseplate including a baseplate body; and one or more mating surfaces formed on one or both of the baseplate body and the cover body to assemble between the cover and the baseplate to each other. The one or more mating surfaces each includes an outermost coating configured to be wear-resistant and lubricating, the outermost coating includes a composite metal plating, and the composite metal plating includes a metal plating with a lubricant embedded therein and/or layered over the metal plating.

### FIELD

This disclosure relates to reticle pods used for reticles. More specifically, this disclosure relates to composite surface plating used to provide wear-resistant and stain-resistant mating surfaces in reticle pods.

### BACKGROUND

Reticle pods are used for containing reticles, such as photolithography masks used in semiconductor processing. Reticle pods can be used for storage and transport of reticles. Reticle pods can include a metal inner pod that is handled and manipulated by one or more tools during processing. The inner pod includes a baseplate and a cover, and the baseplate and the cover contain the reticle and protect the reticle from contamination or physical damage during transport, storage, and processing. Reticle pods include, for example, Extreme Ultraviolet (“EUV”) pods for use with EUV photolithography tools. Reticle pods can include an outer pod with a pod door and a pod dome, which contains the inner pod.

### SUMMARY

This disclosure relates to reticle pods used for reticles. More specifically, this disclosure relates to composite surface plating used to provide wear-resistant and stain-resistant mating surfaces in reticle pods.

According to one embodiment, a device includes a pod. The pod includes a cover including a cover body; a baseplate including a baseplate body; and one or more mating surfaces formed on one or both of the baseplate body and the cover body to assemble between the cover and the baseplate to each other. The one or more mating surfaces each includes an outermost coating configured to be wear-resistant and lubricating, the outermost coating includes a composite metal plating, and the composite metal plating includes a metal plating with a lubricant embedded therein or layered over the metal plating.

According to another embodiment, the composite metal plating is wear-resistant to reduce wear on the one or more mating surfaces, to reduce break out particles from the one or more mating surfaces, and to avoid foreign matter from entering into the pod over a lifetime of the pod being opened and closed within a lithography system.

According to yet another embodiment, wherein the metal plating includes one or more of an electroless nickel plating, an electrolytic nickel plating, an anodized aluminum plating, and a porous anodized aluminum plating. Other types of electroless or electrolytic plating may be used, for example, chrome or aluminum plating.

According to yet another embodiment, the lubricant includes polytetrafluoroethylene and/or molybdenum. The lubricant may be present as particles in the metal plating, for example, the lubricant may be present as sub-millimeter diameter particles which are present in a plated or anodized matrix. In an example, the lubricant is present as particles with the longest dimension in the micron to tens of micron range.

According to yet another embodiment, the composite metal plating includes the lubricant at a weight percentage range to achieve a suitable Rockwell hardness and a suitable dry static coefficient of friction on the one or more mating surfaces to reduce wear on the one or more mating surfaces, to reduce break out particles from the one or more mating surfaces, and to avoid foreign matter from entering into the pod over the lifetime of the pod being opened and closed within the lithography system. In an example, the weight percentage of lubricant is 0.01 percent to 30 percent of the composite metal plating by weight. The weight percent of lubricant may be between 0.1 percent and 10 percent of the composite metal plating by weight. In an embodiment, the weight percent of lubricant is about 3 percent by weight of the composite metal plating.

According to yet another embodiment, the composite metal plating has a range of average pocket size of the lubricant suitable to reduce wear on the one or more mating surfaces, to reduce break out particles from the one or more mating surfaces, and to avoid foreign matter from entering into the pod over the lifetime of the pod being opened and closed within the lithography system.

According to yet another embodiment, the composite metal plating includes a suitable loading percentage of lubricant for the composite metal plating to reduce wear on the one or more seal surfaces, to reduce break out particles from the one or more mating surfaces, and to avoid foreign matter from entering into the pod over the lifetime of the pod being opened and closed within the lithography system.

According to yet another embodiment, the composite metal plating includes a suitable percentage surface area of an outermost surface of the composite metal plating being exposed lubricant particles to reduce wear on the one or more seal surfaces, to reduce break out particles from the one or more mating surfaces, and to avoid foreign matter from entering into the pod over the lifetime of the pod being opened and closed within the lithography system. The composite metal plating may have a gradient of lubricant through a thickness of the composite metal plating, with a highest percentage of lubricant being near a surface of the composite metal plating.

According to yet another embodiment, the composite metal plating includes exposed lubricant particles on the outermost surface having a uniform distribution.

According to yet another embodiment, the composite metal plating has a suitable range of thickness in micrometers to reduce wear on the one or more mating surfaces, to reduce break out particles from the one or more mating surfaces, and to avoid foreign matter from entering into the pod over the lifetime of the pod being opened and closed within the lithography system.

According to yet another embodiment, the lubricant has a uniform distribution within the composite metal plating to reduce wear on the one or more mating surfaces, to reduce break out particles from the one or more mating surfaces, and to avoid foreign matter from entering into the pod over the lifetime of the pod being opened and closed within the lithography system.

According to yet another embodiment, the baseplate body includes aluminum, with the outermost coating formed on the aluminum.

According to yet another embodiment, the one or more mating surfaces are one or more sealing surfaces of the cover and/or the baseplate to seal between the baseplate and the cover, when the cover is placed on the baseplate to avoid foreign matter from entering the pod.

According to yet another embodiment, the composite metal plating extends along a perimeter of one or both of the cover and the baseplate.

According to yet another embodiment, the composite metal plating has a suitable flatness range to reduce wear on the one or more mating surfaces, to reduce break out particles from the one or more mating surfaces, and to avoid foreign matter from entering into the pod when the pod is closed.

According to yet another embodiment, the one or more mating surfaces disposes at one or more corners of one or both of the cover and the baseplate.

According to yet another embodiment, an outer pod dome and an outer pod door, the outer pod dome and the outer pod door configured to accommodate the baseplate and the cover within the outer pod dome when the outer pod door is attached to the outer pod dome.

According to yet another embodiment, the pod is an extreme ultraviolet reticle pod.

According to one embodiment, a method of producing and maintaining a reticle pod includes forming one or more mating surfaces on one or both of a baseplate body of a baseplate and a cover body of a cover to assemble the baseplate and the cover to each other. The one or more mating surfaces each includes an outermost coating, the outermost coating includes a composite metal plating, and the composite metal plating includes a metal plating with a lubricant embedded therein or layered over the metal plating.

According to another embodiment, the forming of the composite metal plating includes heating the at least one of a baseplate body of a baseplate and a cover body of a cover in a plating bath that contains a solution of a metal with suspended particles of the lubricant over a suitable amount of time, at a suitable range of temperature, and with a suitable weight percentage range of the suspended particles of lubricant relative to the metal.

According to yet another embodiment, the method of producing and maintaining a reticle pod includes polishing the composite metal plating according to a resurfacing protocol to remove scratches, wherein the composite metal plating after the polishing has a suitable range of Rockwell hardness and a suitable range of dry static coefficient of friction to reduce wear on the one or more mating surfaces and to avoid foreign matter from entering into pod after the pod being closed. In an embodiment, the mating surface to the composite metal plating is an anodized aluminum surface.

According to yet another embodiment, the method of producing and maintaining a reticle pod includes cleaning the pod with deionized water, wherein the composite metal plating is suitable to reduce staining on the one or more mating surfaces over a lifetime of the pod being cleaned with the deionized water.

According to yet another embodiment, the metal plating includes one or more of an electroless nickel plating, an electrolytic nickel plating, an anodized aluminum plating, and a porous anodized aluminum plating.

According to yet another embodiment, the lubricant includes polytetrafluoroethylene and/or molybdenum.

According to yet another embodiment, the metal being nickel.

According to yet another embodiment, the forming of the one or more mating surfaces are one or more sealing surfaces of the cover and/or the baseplate to seal between the baseplate and the cover, when the cover is placed on the baseplate to avoid foreign matter from entering the pod.

According to yet another embodiment, the composite metal plating extends along a perimeter of one or both of the cover and the baseplate.

According to yet another embodiment, the composite metal plating has a suitable flatness range to reduce wear on the one or more mating surfaces, to reduce break out particles from the one or more mating surfaces, and to avoid foreign matter from entering into the pod when the pod is closed.

According to yet another embodiment, the pod being an extreme ultraviolet reticle pod.

According to yet another embodiment, the pod further includes an outer pod dome and an outer pod door, the outer pod dome and the outer pod door configured to accommodate the baseplate and the cover within the outer pod dome when the outer pod door is attached to the outer pod dome.

### BRIEF DESCRIPTION OF THE DRAWINGS

FIG. 1 is a perspective view of an embodiment of a reticle pod, according to an embodiment.

FIG. 2A is a cross-sectional view of an embodiment of an inner pod of a reticle pod.

FIG. 2B is a cross-sectional view of the inner pod in FIG. 2A when open.

FIG. 3 is a top view of an embodiment of a baseplate in a reticle pod.

FIG. 4 is a bottom view of an embodiment of a cover for a reticle pod.

FIG. 5 is a cross-sectional view of an embodiment of mating surfaces of a baseplate and a cover for a reticle pod.

FIG. 6 is a top view of another embodiment of a baseplate in a reticle pod.

FIG. 7 is a bottom view of another embodiment of a cover for a reticle pod.

FIG. 8 is a cross-sectional view of another embodiment of an inner pod of a reticle pod.

Like reference characters refer to similar features.

### DETAILED DESCRIPTION

This disclosure relates to reticle pods used for reticles. More specifically, this disclosure relates to composite surface plating used to provide wear-resistant and stain-resistant mating surfaces in reticle pods.

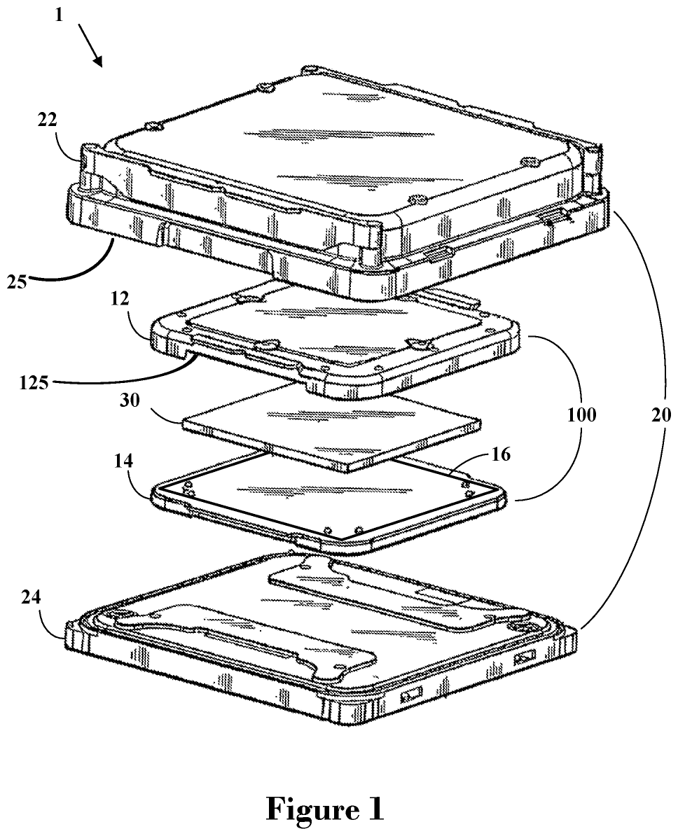

FIG. 1 is a perspective view of a reticle pod 1, according to an embodiment. The reticle pod 1 includes an inner pod 100 and an outer pod 20. For example, the reticle pod 1 can be, but is not limited to, a reticle pod for extreme ultraviolet (“EUV”), such as for example but not limited to the processing of photolithography masks and the like.

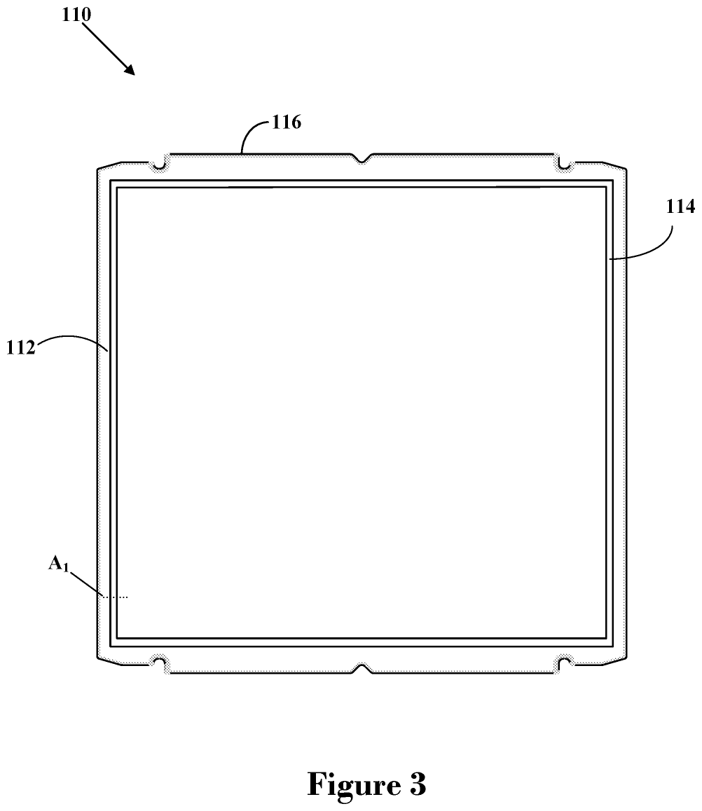

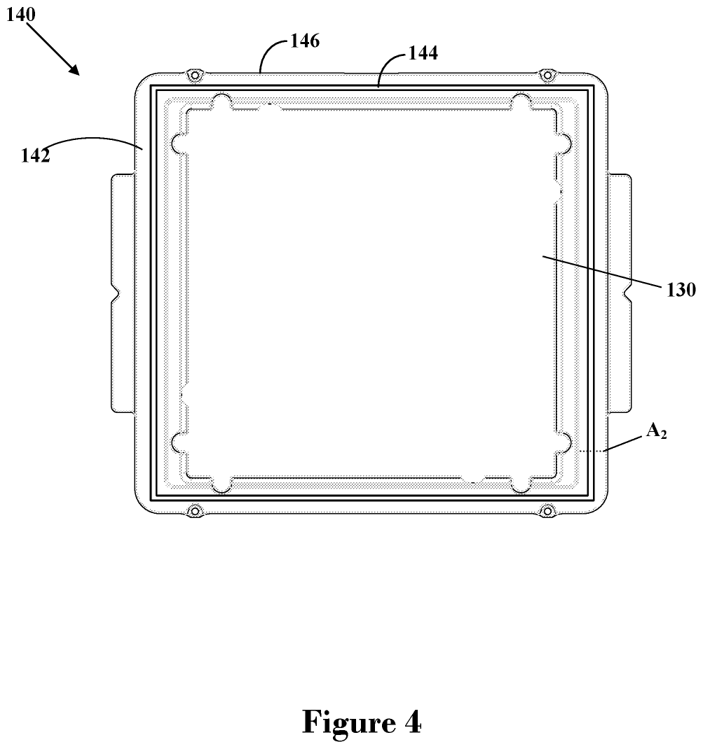

The inner pod 100 includes a cover 12 and a baseplate 14. The cover 12 and the baseplate 14 are configured to be joined together. When joined together, the cover 12 and the baseplate 14 define an internal space 125 sized and shaped to contain a reticle 30. The cover 12 can include a cover body, such as a cover body 146 as shown and described in FIG. 4. The baseplate 14 can include a baseplate body, such as a baseplate body 146 as shown and described in FIG. 3. For example, the reticle 30 can be, but is not limited to, a photolithography mask, which may be used for example but not limited to use in an EUV processing. In some embodiments, at least one of the cover 12 and the baseplate 14 include one or more mating surfaces 16. In one embodiment, the mating surfaces 16 of the cover 12 and the baseplate 14 can seal the inner pod 100 and can be sealing surfaces 16. In some embodiments, the cover 12 and the baseplate 14 each includes at least one of the mating surfaces 16 (obscured in FIG. 1 for the cover 12). Each of the mating surfaces 16 including a wear-resistant outermost coating.

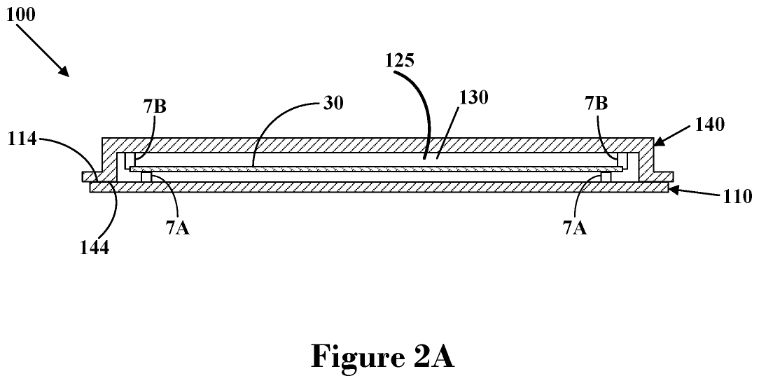

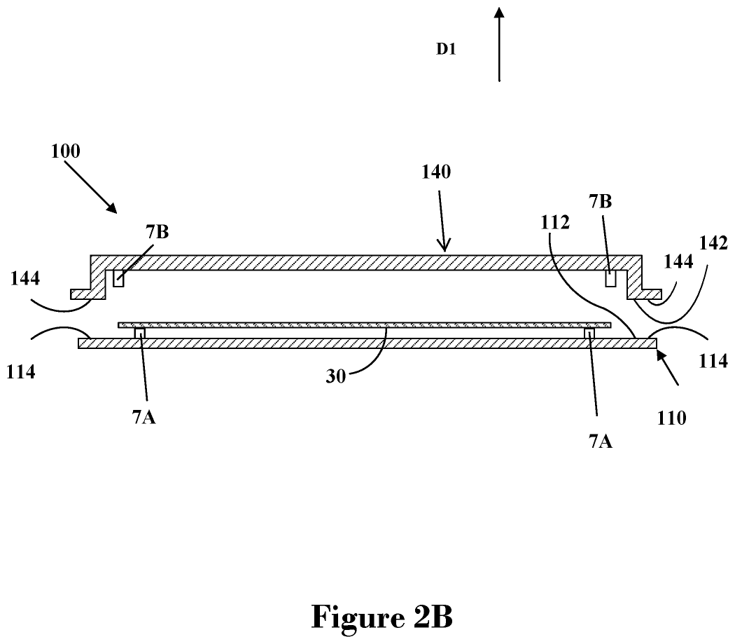

Mating surfaces are two or more surfaces designed to overlap one another. According to an embodiment, mating surfaces can be contacting one another and sealing off a space or an area within a structure. The mating surfaces that contact one another and also sealing off a space or an area within a structure can be sealing surfaces, such as sealing surface 114, 144 as shown and described in FIGS. 2A and 2B.

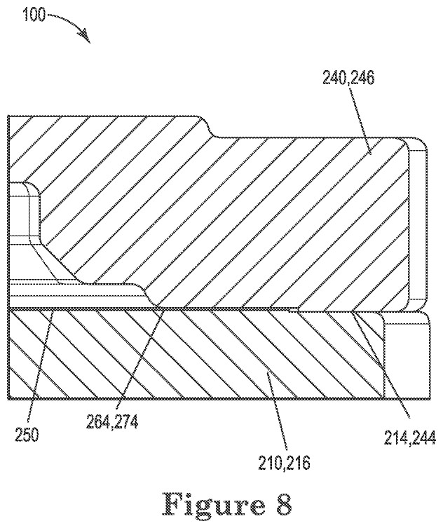

According to another embodiment, mating surfaces can be non-contacting and sealing off with a gap functioning as a particle barrier. Mating surfaces that are non-contacting and sealing off with a gap can also be sealing surfaces, such as sealing surfaces 264, 274 and a gap 250 as shown and described in FIG. 8.

According to yet another embodiment, mating surface can be contacting surfaces and providing no sealing effect, such as mating surfaces 214, 244 as shown and described in FIG. 8.

In another embodiment, the mating surface 16 separating the cover 12 from the baseplate 14 in a closed position can create translated contact surfaces with a small gap between the mating surfaces of the cover and the baseplate. In this embodiment, the non-contacting portion of the mating surfaces creates a gap that functions as a particle barrier. The portion of non-contacting mating surfaces can be a sealing surface in this example. The gap can function as a particle barrier while reducing wears on the seal or mating surfaces. The gap can be around 0.005 mm to 0.010 mm.

The outer pod 20 includes an outer pod dome 22 and an outer pod door 24. The outer pod 20 is configured to accommodate the inner pod 100 within an internal space 25 defined between the outer pod dome 22 and the outer pod door 24. The outer pod dome 22 can be secured to the outer pod door 24 to enclose the internal space 25 and contain the inner pod 100, for example during transport and handling of the reticle pod 1. The outer pod dome 22 and the outer pod door 24 can each include or be made entirely of one or more polymer materials.

FIGS. 2A and 2B show cross-sectional views of an embodiment of the inner pod 100 of the reticle pod 1 of FIG. 1. FIG. 2A shows the inner pod 100 when closed. FIG. 2B shows the inner pod 100 when open. The inner pod 100 has an internal space 125 with a reticle containment portion 130 for containing the reticle 30. The inner pod 100 can include reticle supports 7A and reticle contacts 7B within the reticle containment portion 130 for supporting and restraining the reticle 30 within the inner pod 100.

The inner pod 100 includes a baseplate 110 and a cover 140. The baseplate 110 and the cover 140 are configured to be joined together. As shown in FIG. 2A, the internal space 125 of the inner pod 100 is enclosed (e.g., closed) by placing the cover 140 on the baseplate 110. In one embodiment, the cover 140 directly contacts the baseplate 110. In particular, the bottom 142 of the cover 140 contacts the top 112 of the baseplate 110. The inner pod 100 is opened by moving the cover 140 away from the baseplate 110 (e.g., by moving the cover upwards in direction Di, etc.). For example, an external tool (e.g., automated arm, etc.) opens the inner pod 100 to access the reticle containment portion 130 and removes the reticle 30.

The baseplate 110 and the cover 140 include one or more mating surface(s) 114,144. According to an embodiment, the mating surfaces 114, 144 contact each other creating a physical barrier and seal between the baseplate 110 and the cover 140. The mating surfaces 114, 144 can be sealing surfaces in this embodiment. The mating surfaces 114, 144 are configured to reduce or prevent external contaminants or foreign matter, such as dust, break off particles, or the likes, from entering the inner pod 100 by passing between the baseplate 110 and the cover 140 when the reticle pod 100 is closed. For example, the baseplate 110 can include a first sealing surface (e.g., mating surface 114) that is configured to directly contact the cover 140, and the cover 140 can include a second sealing surface (e.g., mating surface 144) that is configured to directly contact the baseplate 110.

FIG. 3 is a top view of an embodiment of the baseplate 110 for the reticle pod 100. FIG. 3 shows the top 112 of the baseplate 110. The cover 140 (shown in FIG. 4) is configured to be placed onto the top 112 of the baseplate 110.

The baseplate 110 includes the mating surface 114 and a baseplate body 116. The mating surface 114 is formed on the baseplate body 116. The baseplate 110 shown in FIG. 3 includes a single continuous mating surface 114. In an embodiment, the mating surface 114 extends along the entire perimeter of the baseplate 110. However, the baseplate 110 can include multiple mating surfaces in an embodiment. For example, separate mating surfaces 114 can be provided at locations in which greater amounts of wear occurs between the baseplate 110 and the cover 140. In an embodiment, the mating surface(s) 114 of the baseplate 110 can extend along a portion of or all of the perimeter of the baseplate 110.

FIG. 4 is a bottom view of an embodiment of the cover 140 for the inner pod 100. FIG. 4 shows the bottom 142 of the cover 140. The bottom 142 of the cover 140 is configured to contact the top 112 of the baseplate 110 (shown in FIG. 3) when the cover 140 is placed on the baseplate 110 (shown in FIG. 3). The cover 140 can include the reticle containment portion 130 within the inner pod 100 of FIG. 1.

The cover 140 includes the mating surface 144 and a cover body 146. The mating surface 144 is formed on the cover body 146. The cover 140 as shown in FIG. 4 includes a single continuous mating surface 144. However, the cover 140 may include multiple mating surfaces in an embodiment. For example, each of the mating surfaces 144 can extend along a portion or all of the perimeter of the cover 140. For example, the separate mating surfaces 144 can be provided at locations in which a greater amount of wear occurs between the baseplate 110 and the cover 140.

In an embodiment, the mating surface 144 extends along the entire perimeter of the cover 140. Accordingly, when the cover 140 is placed on the baseplate 110, the mating surface 144 is disposed extending along the entire perimeter of the baseplate 110. In some embodiments, the one or more mating surfaces 114 of the baseplate 110 (shown in FIG. 3) and the one or more mating surfaces 144 of the cover 140 can be disposed extending around the entire perimeter of the baseplate 110 in combination. For example, the mating surface(s) 114 of the baseplate 110 may not extend along the entire perimeter of the baseplate 110, and the mating surface(s) 144 of the cover 140 extend along the portion(s) of the perimeter of the baseplate 110 without the mating surface(s) 114. When considered in combination, the mating surface(s) 114 of the baseplate 110 and the mating surfaces 144 of the cover 140 may extend along the entire perimeter of the baseplate 110.

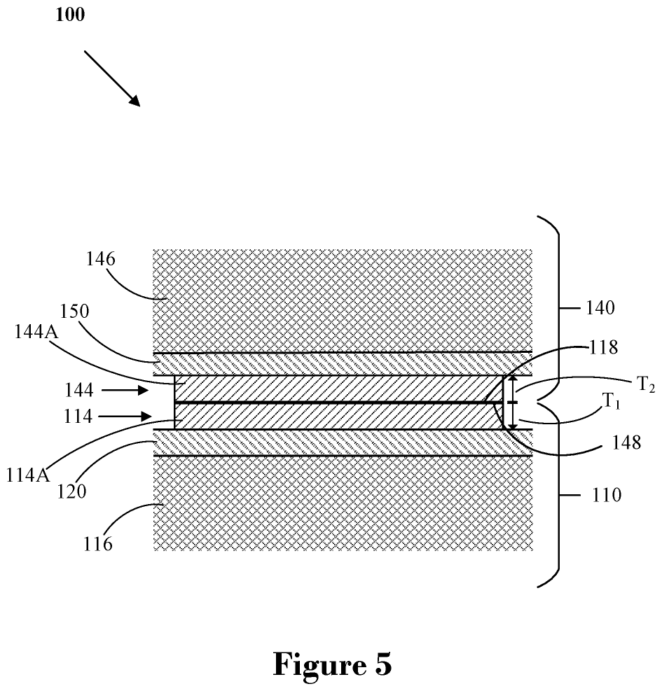

FIG. 5 is a cross-sectional view across the mating surfaces 114, 144 of the baseplate 110 and the cover 140. For example, the cross-section in FIG. 5 extends through the dashed line A₁ in FIG. 3 and the dashed line A2 in FIG. 4. FIG. 5 shows an exemplary structure and interaction of the mating surfaces 114, 144 when the cover 140 is placed on the baseplate 110 and the inner pod 100 is closed (e.g., as shown in FIG. 2B).

The mating surface 114 is formed on the baseplate body 116, and the mating surface 144 is formed on the cover body 146. The baseplate body 116 and the cover body 146 are respectively made of metal. The baseplate body 116 and the cover body 146 can be made of the same or different metal. In an embodiment, the baseplate body 116 includes aluminum and the mating surface 114 is formed on the aluminum of the baseplate body 116. In an embodiment, the cover body 146 includes aluminum and the mating surface 144 is formed on the aluminum of the cover body 146.

Each mating surface 114, 144 includes a wear-resistant outermost coating 114A, 144A. Each wear-resistant outermost coating 114A, 144A extends along the entire length of its mating surface 114, 144. For example, the wear-resistant outermost coating 114A would extend along the entire perimeter of the baseplate 110 as similarly described above and shown in FIG. 3 for the mating surface 114.

Along each mating surface 114 of the baseplate 110, a wear-resistant outermost coating 114A provides the outer surface 118 of the baseplate 110. Along each mating surface 144 of the cover 140, the wear-resistant outmost coating 144A provides the outer surface 148 of the cover 140. Accordingly, when the cover 140 is placed on the baseplate 110, the cover 140 contacts the baseplate 110 via the one or more wear-resistant outermost surfaces 114A, 144A.

As shown in FIG. 5, an inner layer 120 is provided between the wear-resistant outermost coating 114A and the baseplate body 116. The inner layer 120 is formed on the baseplate body 116, and the wear-resistant outermost coating 114A is on the stacked inner layer 120 and baseplate body 116. For example, the inner layer 120 can be, but is not limited to, one or more of nickel, anodized aluminum layer, porous anodized aluminum layer, or the like.

In an embodiment, the baseplate 110 may not include the inner layer 120. For example, the wear-resistant outermost coating 114A can be formed directly on the material of the baseplate body 116. In another embodiment, a plurality of inner layers 120 can be provided between the wear-resistant outermost coating 114A and the baseplate body 116. For example, the baseplate body 116 may include inner layer(s) 120 that improves one or more properties of the baseplate 110 (e.g., decreased reactivity, increased strength, etc.), and/or one or more properties of the wear-resistant outermost coating 114A (e.g., increased strength, increased adhesion of the wear-resistant outermost coating, etc.). In an embodiment, the cover 140 may include an inner layer 150 in a similar manner as described above for the inner layer 120.

In FIGS. 2A-5, both the baseplate 110 and the cover 140 are provided with at least one mating surfaces 114, 144 that has wear-resistant outermost coatings 114A, 144A. The mating surface 114 of the baseplate 110 directly contacts the mating surface 144 of the cover 140. More particularly, the wear-resistant outermost coating 114A of the baseplate 110 directly contacts the wear-resistant outermost coating 144A of the cover 140. The mating surface 114, 144 and its wear-resistant outermost coating 114A, 144A may directly contact a material other than a wear-resistant outermost coating. For example, the mating surfaces 114, 144 and their wear-resistant outer coatings 114A, 144A can directly contact the metal of the opposing baseplate body 116 or cover body 146, or a coating on said opposing baseplate body 116 or cover body 146 (e.g., the inner layer 120, the inner layer 150, etc.) In other embodiments, a mating surface and its wear-resistant outermost coating may not contact or may not directly contact the wear-resistant outermost coating of an opposing mating surface. In yet another embodiment, the wear-resistant outermost coatings can extend beyond the mating surfaces 114, 144. For example, the wear-resistant outermost coatings can cover a portion or all the bottom 142 of the cover 140 and/or the top 112 of the baseplate 100. By coating beyond the mating surfaces 114, 144, the manufacturing complexities and variabilities may be reduced by reducing or eliminating masking of the cover 140 and/or the baseplate 100 during plating.

According to one embodiment, the wear-resistant coatings 114A, 144A can include the composite metal plating. The composite metal plating includes a metal plating and a second material being a lubricant. The lubricant can include one or more of or a combination of any polymers, compositions of chemicals, materials, and structures that reduce the coefficient of friction on any surfaces of the EUV pod. In an embodiment, the lubricant can reduce the coefficient of friction at on any mating surfaces of the EUV pod. In an embodiment, the lubricant can be, but is not limited to, one or more of polytetrafluoroethylene (“PTFE”), molybdenum, and the like. The molybdenum can be molybdenum disulfide embedded in the porous anodized aluminum plating. The molybdenum disulfide embedded in a porous anodized aluminum plating can be commercially known as KASHIMA coat.

The composite metal plating can be a single layered plating with the second material embedded within the metal plating. According to another embodiment, the composite metal plating can be a layered structure with a composite layer provided over the metal layer. The composite layer can be the wear-resistant coating 114A, 144A and the metal plating can be inner layer 120, 150.

The composite plating is wear-resistant to reduce wear on the one or more mating surfaces, to reduce break out particles from the one or more mating surfaces, and to avoid foreign matter from entering into the inner pod 100 over a lifetime of the inner pod 100 being opened and closed within a lithography system.

The composite metal plating can be, but it is not limited to, one or more of an electroless nickel plating, an electrolytic metal plating, an anodized aluminum plating, a porous anodized aluminum plating, and the like. The composite metal plating includes a lubricant that reduces friction on a surface coated or plated with the lubricant. The lubricant can be chemical compounds or polymer particles that, when added to the metal plating, reduces the overall friction on the plated surface. The lubricant can be included in the plating bath in a form of a solution or suspended particles having a suitable load percentage or a suitable weight percentage, for a suitable amount of time, and at a suitable temperature or temperature profiles over time.

The lubricant can take on various suitable structures or forms relative to the metal plating that results in improved surface characteristics of the EUV pod. In an embodiment, the lubricant can promote interfacial slip at the mating surfaces, between the mating surfaces, or both. The improved surface characteristics can be achieved by, but not limited to, lowering the coefficient of friction of the metal plating. For example, the lubricant can provide an advantage of increased wear resistance of the EUV pod. In an embodiment, the lubricant may include, but is not limited to, one or more of particles, agglomerations, films, layers, different phases, and the like.

In an embodiment, the plated surface has some lubricant exposed. The lubricant can take on various forms embedded in and/or layered on the metal plating. In one non-limiting example, the lubricant is a material that may be in the form of particles in certain embodiments. It will be appreciated that the lubricant may be in forms other than particles.

In an embodiment where the lubricant is in the form of particles, the lubricant can be affixed in the metal plating from lubricant particles suspended in the plating bath. The lubricant can be affixed in the metal plating by being embedded entirely or partially in the metal plating.

In an embodiment, the composite metal plating can include one or more lubricant materials filled inside pockets of the metal plating, and at least some of the lubricant materials are exposed on the outermost surface of the composite metal plating.

In an embodiment, the lubricant can be coated over the metal plating in one or more layers.

The composite metal plating includes the lubricant at a weight percentage range to achieve a suitable Rockwell hardness and a suitable dry static coefficient of friction on the one or more mating surfaces 114, 144 to reduce wear on the one or more mating surfaces 114, 144 and to avoid foreign matter from entering into the inner pod 100 over the lifetime of the inner pod 100 being opened and closed within the lithography system.

The composite metal plating can have a suitable range of Rockwell C hardness. In an embodiment, has a Rockwell C hardness of about or greater than a suitable Rockwell C hardness. In some embodiments, the inclusion of the lubricant in the composite metal plating reduces the Rockwell C hardness of the composite metal plating relative to a plating without lubricant. Rockwell C hardness can be measured and determined according to ASTM E18-20.

As shown in FIG. 5, the composite metal plating can a thickness T₁, T₂ that is smaller than the thickness of the baseplate body 116 or the cover body 146 on which its formed. In an embodiment, the thickness of a wear-resistant outermost coating 114A, 144A has a suitable range in micrometers. In an embodiment, the thickness of a wear-resistant outermost coating 114A, 144A has a suitable thickness in micrometers. The size of the particles in the composite metal plating may be selected based on the thickness of the composite metal plating. In an embodiment, the particles have a mean largest axis length that is less than 50% of the thickness of the composite plating. In other embodiments, the particles have a mean largest axis length that is less than 20% of the thickness of the composite plating. The particles may be shaped, for example, as rods or plates.

The composite metal plating can include a suitable range of pocket size of the lubricant or a range of average pocket size of the lubricant suitable to reduce wear on the one or more mating surfaces and to avoid foreign matter from entering into the inner pod 100 over the lifetime of the inner pod 100 being opened and closed within the lithography system.

The composite metal plating includes a suitable loading percentage at an outermost surface of the composite metal plating. The loading percentage can be a percentage of total area of with exposed lubricant, such as PTFE, at the mating surfaces 114, 144. The percentage of total area with exposed lubricant at the mating surfaces 114, 144 may be between 1 percent and 80 percent. In an example, the percentage of total area with exposed lubricant at the mating surfaces 114, 144 may be between 10 percent and 50 percent. The exposed lubricant can be lubricant particles embedded in the metal plating, the lubricant particles can be uniformly distributed on the exposed surface of the mating surfaces 114, 144. The lubricant particles can be uniformly distributed within the composite metal plating.

The composite metal plating is suitable to reduce staining on the one or more mating surfaces over the lifetime of the inner pod 100 being cleaned with deionized water. The lifetime of the inner pod 100 can be about 60,000 cycles of the inner pod 100 being opened and closed.

The composite metal plating can be formed by placing the baseplate 110 or the cover 140 in a plating bath that contains a solution of a metal with suspended particles of the lubricant at a suitable range of time, at a suitable range of temperature, and with a suitable weight percentage range of the suspended particles of lubricant relative to the metal. The composite metal plating formed on the one or more mating surfaces 114, 144 of the baseplate 110 or the cover 140 can reduce wear on the one or more mating surfaces, reduce break out particles from the one or more mating surfaces, and avoid foreign matter from entering into the pod over the lifetime of the pod being opened and closed within the lithography system. The suspended particles of the lubricant have a suitable average particle sizes. The metal can nickel. The formed mating surfaces can have a suitable range of flatness.

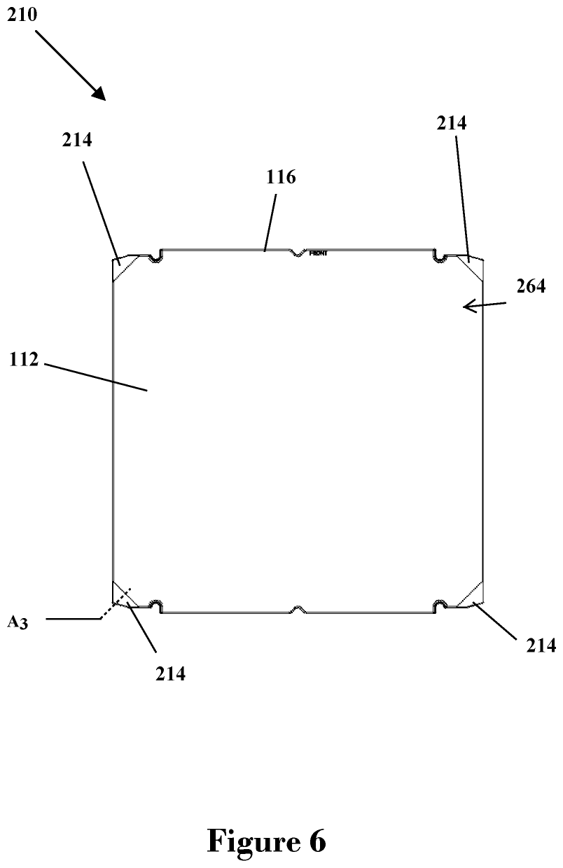

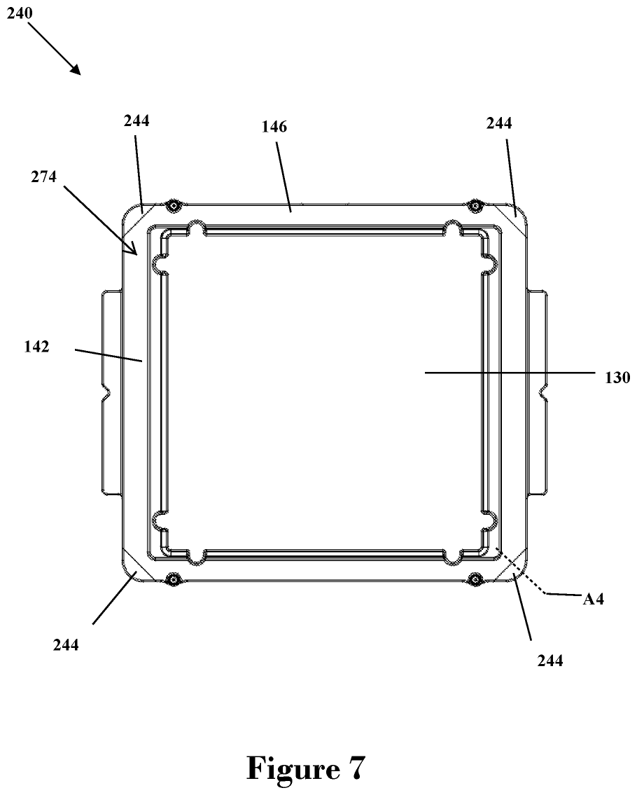

FIG. 6 is a top view of yet another embodiment of a baseplate 210 of a reticle pod 100. A cover 240 (as shown in FIG. 7) can be placed over the baseplate 210 according to FIG. 8. Features that are the same as features in the inner pod 100 are referenced using the same or similar reference numerals.

The baseplate 210 includes a mating surface 214. The mating surface 214 is formed on the baseplate body 216. The mating surface 214 of the baseplate 210 contacts with a mating surface 244 of the cover 240 when the cover 240 is positioned on over the baseplate 210. The mating surface 214 can include one or more portions of the mating surface 214 that are continuous along a perimeter of the baseplate 210 or broken into multiple segments of disjointed portions of the mating surface 214. The mating surface 214 of the baseplate 210 or each portion of the mating surface 214 can be protruded from, at the same level of, or recessed into the top 112 of the baseplate 210, depending on the configuration of the mating surface 244 or the corresponding portion of the mating surface 244 of the cover 140 (shown in FIG. 8).

The baseplate 210 in FIG. 6 includes four portions of disjointed mating surface 214. A portion of the mating surface 214 is disposed at each corner of the baseplate 210. The mating surface 214 is recessed from the top 112 into the baseplate 210. Each portion or disjointed mating surface 214 is recessed below the top 112 of the baseplate 210 by a same depth.

As shown in FIG. 6, the baseplate 210 includes a mating surface 264 that seals the reticle containment portion 130 when the inner pod 100 is closed. This mating surface 264 can be a sealing surface 264 in this example. When the cover 240 is placed onto the top 112 of the baseplate 210, the sealing surface 264 and a sealing surface 274 of the cover 240 (shown in FIG. 7) form a particle barrier that reduces or prevents foreign matter, such as foreign matter, such as dust, break off particles, or the likes, from entering the inner pod 100.

FIG. 7 is a bottom view of another embodiment of the cover 240 for a reticle pod 100. The cover 240 can be placed over the baseplate 210 (shown in FIG. 6) according to FIG. 8. Features that are the same as features in the inner pod 100 are referenced using the same or similar reference numerals.

The cover 240 includes a mating surface 244. The mating surface 244 is formed on the cover body 146. The mating surface 244 of the cover 210 contacts with the mating surface 244 of the baseplate 210 when the cover 240 is placed over the baseplate 210. The mating surface 244 can include one or more portions that are connected or disjointed from one and another. The mating surface 244 of the cover 240 or each portion of the mating surface 244 can be protruded from, at the same level of, or recessed into the bottom 142 of the cover 240, depending on the configuration of the mating surface 214 or the corresponding portion of the mating surface 214 of the baseplate 210 (shown in FIG. 7).

The cover 240 in FIG. 7 includes four portions of disjointed mating surface 244. A portion of the mating surface 244 is disposed at each corner of the cover 240. The mating surface 244 is protruded from the bottom 142 out of the cover 240. Each portion or disjointed mating surface 244 is protruded above the bottom 142 of the cover 240 by a same height.

As shown in FIG. 7, the cover 240 includes a mating surface 274 that seals the reticle containment portion 130 when the inner pod 100 is closed. This mating surface 274 can be a sealing surface 274 in this example. When the cover 240 is placed onto the top 112 of the baseplate 210, the sealing surface 264 of the baseplate 210 (shown in FIG. 6) and the sealing surface 274 of the cover 240 form the particle barrier that reduces or prevents foreign matter, such as foreign matter, such as dust, break off particles, or the likes, from entering the inner pod 100.

FIG. 8 is a cross-sectional view across the mating surfaces 214, 244 of the baseplate 210 and the cover 240. For example, the cross-section in FIG. 8 extends through the dashed line A3 in FIG. 6 and the dashed line A4 in FIG. 7. FIG. 8 shows a structure and interaction of mating surfaces 214, 244 and sealing surfaces 264, 274 when the cover 240 is placed on the baseplate 210.

The mating surface 214 is formed on the baseplate body 216, and the mating surface 244 is formed on the cover body 246. The baseplate body 216 and the cover body 246 are respectively made of metal. The baseplate body 216 and the cover body 246 can be made of the same or different metals. In an embodiment, the baseplate body 216 includes aluminum and the mating surface 214 is formed on the aluminum of the baseplate body 216. In an embodiment, the cover body 246 includes aluminum and the mating surface 144 is formed on the aluminum of the cover body 246.

One or more of the mating surface 214, 244, 264, 274 can include a wear-resistant outermost coating. The wear-resistant outermost coating can extend along the entire area of its mating surface 214, 244, 264, 274. The wear-resistant outermost coating can have the properties of the wear-resistant outermost coating 114A, 144A as shown and described for FIG. 5.

The mating surfaces 214 and 244 are configured such that the sealing surfaces 264 and 274 are spaced away from each other and forming a gap 250 when the inner pod 100 is closed and when the cover 240 is placed over the baseplate 210 as shown in FIG. 8. The gap 250 has a suitable thickness to reduce or prevent external contaminants or foreign matter, such as dust, break off particles, or the likes, from entering the inner pod 100 by passing between the baseplate 210 and the cover 240. The gap 250 can be between at or about 0.005 mm to at or about 0.010 mm thick.

Aspects. It is noted that any of aspects 1-18 can be combined with any of aspects 19-30.
Aspect 1. A device, comprising:

a pod, the pod includes:

a cover including a cover body;

a baseplate including a baseplate body; and

one or more mating surfaces formed on one or both of the baseplate body and the cover body to assemble the cover and the baseplate to each other, wherein

the one or more mating surfaces each includes an outermost coating configured to be wear-resistant and lubricating,

the outermost coating includes a composite metal plating, and

the composite metal plating includes a metal plating with a lubricant embedded therein and/or layered over the metal plating.

Aspect 2. The device of aspect 1, wherein the composite metal plating is wear-resistant to reduce wear on the one or more mating surfaces, to reduce break out particles from the one or more mating surfaces, and to avoid foreign matter from entering into the pod over a lifetime of the pod being opened and closed within a lithography system.
Aspect 3. The device of any one of aspects 1-2, wherein the metal plating includes one or more of an electroless nickel plating, an electrolytic nickel plating, an anodized aluminum plating, and a porous anodized aluminum plating.
Aspect 4. The device of any one of aspects 1-3, wherein the lubricant includes polytetrafluoroethylene and/or molybdenum.
Aspect 5. The device of any one of aspects 1-4, wherein the composite metal plating includes the lubricant at a weight percentage range to achieve a suitable Rockwell hardness and a suitable dry static coefficient of friction on the one or more mating surfaces to reduce wear on the one or more mating surfaces, to reduce break out particles from the one or more mating surfaces, and to avoid foreign matter from entering into the pod over the lifetime of the pod being opened and closed within the lithography system.
Aspect 6. The device of any one of aspects 1-5, wherein the composite metal plating has a range of average pocket size of the lubricant suitable to reduce wear on the one or more mating surfaces, to reduce break out particles from the one or more mating surfaces, and to avoid foreign matter from entering into the pod over the lifetime of the pod being opened and closed within the lithography system.
Aspect 7. The device of any one of aspects 1-6, wherein the composite metal plating includes a suitable loading percentage of lubricant for the composite metal plating to reduce wear on the one or more seal surfaces, to reduce break out particles from the one or more mating surfaces, and to avoid foreign matter from entering into the pod over the lifetime of the pod being opened and closed within the lithography system.
Aspect 8. The device of any one of aspects 1-7, wherein the composite metal plating includes a suitable percentage surface area of an outermost surface of the composite metal plating being exposed lubricant particles to reduce wear on the one or more seal surfaces, to reduce break out particles from the one or more mating surfaces, and to avoid foreign matter from entering into the pod over the lifetime of the pod being opened and closed within the lithography system.
Aspect 9. The device of any one of aspects 1-8, wherein the composite metal plating includes exposed lubricant particles on the outermost surface have a uniform distribution.
Aspect 10. The device of any one of aspects 1-9, wherein the composite metal plating has a suitable range of thickness in micrometers to reduce wear on the one or more mating surfaces, to reduce break out particles from the one or more mating surfaces, and to avoid foreign matter from entering into the pod over the lifetime of the pod being opened and closed within the lithography system.
Aspect 11. The device of any one of aspects 1-10, wherein the lubricant has a uniform distribution within the composite metal plating to reduce wear on the one or more mating surfaces, to reduce break out particles from the one or more mating surfaces, and to avoid foreign matter from entering into the pod over the lifetime of the pod being opened and closed within the lithography system.
Aspect 12. The device of any one of aspects 1-11, wherein the baseplate body includes aluminum, the outermost coating formed on the aluminum.
Aspect 13. The device of any one of aspects 1-12, wherein the one or more mating surfaces are one or more sealing surfaces of the cover and/or the baseplate to seal between the baseplate and the cover, when the cover is placed on the baseplate to avoid foreign matter from entering the pod.
Aspect 14. The device of any one of aspects 1-13, wherein the composite metal plating extends along a perimeter of one or both of the cover and the baseplate.
Aspect 15. The device of any one of aspects 1-14, wherein the composite metal plating has a suitable flatness range to reduce wear on the one or more mating surfaces, to reduce break out particles from the one or more mating surfaces, and to avoid foreign matter from entering into the pod when the pod is closed.
Aspect 16. The device of any one of aspects 1-15, wherein the one or more mating surfaces disposes at one or more corners of one or both of the cover and the baseplate.
Aspect 17. The device of any one of aspects 1-16, further comprises

an outer pod dome and an outer pod door, the outer pod dome and the outer pod door configured to accommodate the baseplate and the cover within the outer pod dome when the outer pod door is attached to the outer pod dome.

Aspect 18. The device of any one of aspects 1-17, wherein the pod being an extreme ultraviolet reticle pod.
Aspect 19. A method of producing and maintaining a reticle pod, comprising:

forming one or more mating surfaces on one or both of a baseplate body of a baseplate and a cover body of a cover to assemble the baseplate and the cover to each other, wherein

the one or more mating surfaces each includes an outermost coating, the outermost coating includes a composite metal plating, and

the composite metal plating includes a metal plating with a lubricant embedded therein and/or layered over the metal plating.

Aspect 20. The method of aspect 19, wherein the forming of the composite metal plating includes

heating the at least one of a baseplate body of a baseplate and a cover body of a cover in a plating bath that contains a solution of a metal with suspended particles of the lubricant over a suitable amount of time, at a suitable range of temperature, and with a suitable weight percentage range of the suspended particles of lubricant relative to the metal.

Aspect 21. The method of any one of aspects 19-20, further comprises

polishing the composite metal plating according to a resurfacing protocol to remove scratches, wherein the composite metal plating after the polishing has a suitable range of Rockwell hardness and a suitable range of dry static coefficient of friction to reduce wear on the one or more mating surfaces and to avoid foreign matter from entering into pod after the pod being closed.

Aspect 22. The method of any one of aspects 19-21, further comprises

cleaning the pod with deionized water, wherein the composite metal plating is suitable to reduce staining on the one or more mating surfaces over a lifetime of the pod being cleaned with the deionized water.

Aspect 23. The method of any one of aspects 19-22, wherein the metal plating includes one or more of an electroless nickel plating, an electrolytic nickel plating, an anodized aluminum plating, and a porous anodized aluminum plating.
Aspect 24. The method of any one of aspects 19-23, wherein the lubricant includes polytetrafluoroethylene and/or molybdenum.
Aspect 25. The method of any one of aspects 19-24, wherein the metal being nickel.
Aspect 26. The method of any one of aspects 19-25, wherein the forming of the one or more mating surfaces are one or more sealing surfaces of the cover and/or the baseplate to seal between the baseplate and the cover, when the cover is placed on the baseplate to avoid foreign matter from entering the pod.
Aspect 27. The method of any one of aspects 19-26, wherein the composite metal plating extends along a perimeter of one or both of the cover and the baseplate.
Aspect 28. The method of any one of aspects 19-27, wherein the composite metal plating has a suitable flatness range to reduce wear on the one or more mating surfaces, to reduce break out particles from the one or more mating surfaces, and to avoid foreign matter from entering into the pod when the pod is closed.
Aspect 29. The method of any one of aspects 19-28, wherein the pod being an extreme ultraviolet reticle pod.
Aspect 30. The method of any one of aspects 19-29, wherein the pod further comprises:

an outer pod dome and an outer pod door, the outer pod dome and the outer pod door configured to accommodate the baseplate and the cover within the outer pod dome when the outer pod door is attached to the outer pod dome.

What is claimed is:

1. A device, comprising:
a pod, the pod includes:
a cover including a cover body;
a baseplate including a baseplate body; and
one or more mating surfaces formed on one or both of the baseplate body and the cover body to assemble the cover and the baseplate to each other, wherein
the one or more mating surfaces each includes an outermost coating configured to be wear-resistant and lubricating,
the outermost coating includes a composite metal plating, and
the composite metal plating includes a metal plating with a lubricant embedded therein and/or layered over the metal plating.

2. The device of claim 1, wherein the composite metal plating is wear-resistant to reduce wear on the one or more mating surfaces, to reduce break out particles from the one or more mating surfaces, and to avoid foreign matter from entering into the pod over a lifetime of the pod being opened and closed within a lithography system.

3. The device of claim 1, wherein the metal plating includes one or more of an electroless nickel plating, an electrolytic nickel plating, an anodized aluminum plating, and a porous anodized aluminum plating.

4. The device of claim 3, wherein the lubricant includes polytetrafluoroethylene and/or molybdenum.

5. The device of claim 1, wherein the composite metal plating includes the lubricant at a weight percentage range to achieve a suitable Rockwell hardness and a suitable dry static coefficient of friction on the one or more mating surfaces to reduce wear on the one or more mating surfaces, to reduce break out particles from the one or more mating surfaces, and to avoid foreign matter from entering into the pod over the lifetime of the pod being opened and closed within the lithography system.

6. The device of claim 1, wherein the composite metal plating has a range of average pocket size of the lubricant suitable to reduce wear on the one or more mating surfaces, to reduce break out particles from the one or more mating surfaces, and to avoid foreign matter from entering into the pod over the lifetime of the pod being opened and closed within the lithography system.

7. The device of claim 1, wherein the composite metal plating includes a suitable loading percentage of lubricant for the composite metal plating to reduce wear on the one or more seal surfaces, to reduce break out particles from the one or more mating surfaces, and to avoid foreign matter from entering into the pod over the lifetime of the pod being opened and closed within the lithography system.

8. The device of claim 1, wherein the composite metal plating includes a suitable percentage surface area of an outermost surface of the composite metal plating being exposed lubricant particles to reduce wear on the one or more seal surfaces, to reduce break out particles from the one or more mating surfaces, and to avoid foreign matter from entering into the pod over the lifetime of the pod being opened and closed within the lithography system.

9. The device of claim 1, wherein the composite metal plating includes exposed lubricant particles on the outermost surface have a uniform distribution.

10. The device of claim 1, wherein the composite metal plating has a suitable range of thickness in micrometers to reduce wear on the one or more mating surfaces, to reduce break out particles from the one or more mating surfaces, and to avoid foreign matter from entering into the pod over the lifetime of the pod being opened and closed within the lithography system.

11. The device of claim 1, wherein the lubricant has a uniform distribution within the composite metal plating to reduce wear on the one or more mating surfaces, to reduce break out particles from the one or more mating surfaces, and to avoid foreign matter from entering into the pod over the lifetime of the pod being opened and closed within the lithography system.

12. The device of claim 1, wherein the baseplate body includes aluminum, the outermost coating formed on the aluminum.

13. The device of claim 1, wherein the one or more mating surfaces are one or more sealing surfaces of the cover and/or the baseplate to seal between the baseplate and the cover, when the cover is placed on the baseplate to avoid foreign matter from entering the pod.

14. The device of claim 1, wherein the composite metal plating extends along a perimeter of one or both of the cover and the baseplate.

15. The device of claim 1, wherein the composite metal plating has a suitable flatness range to reduce wear on the one or more mating surfaces, to reduce break out particles from the one or more mating surfaces, and to avoid foreign matter from entering into the pod when the pod is closed.

16. The device of claim 1, wherein the one or more mating surfaces disposes at one or more corners of one or both of the cover and the baseplate.

17. The device of claim 1, further comprises an outer pod dome and an outer pod door, the outer pod dome and the outer pod door configured to accommodate the baseplate and the cover within the outer pod dome when the outer pod door is attached to the outer pod dome.

18. The device of claim 1, wherein the pod being an extreme ultraviolet reticle pod.

19. A method of producing and maintaining a reticle pod, comprising:
forming one or more mating surfaces on one or both of a baseplate body of a baseplate and a cover body of a cover to assemble the baseplate and the cover to each other, wherein
the one or more mating surfaces each includes an outermost coating, the outermost coating includes a composite metal plating, and
the composite metal plating includes a metal plating with a lubricant embedded therein and/or layered over the metal plating.

20. The method of claim 19, further comprises
polishing the composite metal plating according to a resurfacing protocol to remove scratches.
